(19) United States
(12) Patent Application Publication
(10) Pub. No.: US 2014/0374900 A1
(43) Pub. Date: Dec. 25, 2014

(54) SEMICONDUCTOR PACKAGE AND METHOD OF FABRICATING THE SAME

(71) Applicants: Heungkyu Kwon, Seongnam-si (KR); Jongkook Kim, Hwaseong-si (KR)

(72) Inventors: Heungkyu Kwon, Seongnam-si (KR); Jongkook Kim, Hwaseong-si (KR)

(21) Appl. No.: 14/242,094

(22) Filed: Apr. 1, 2014

(30) Foreign Application Priority Data
Jun. 21, 2013 (KR) 10-2013-0071774

(51) Int. Cl. H01L 23/498

(52) U.S. Cl. CPC H01L 23/49811
USPC 257/737

(57) ABSTRACT

A semiconductor package includes memory I/O bumps and power/ground voltage bumps which are disposed at different positions from each other. In the semiconductor package, memory chips are disposed side by side, and a passivation layer is interposed between a conductive pad and a bump.

### CROSS-REFERENCE TO RELATED APPLICATIONS

This U.S. non-provisional patent application claims priority under 35 U.S.C. §119 to Korean Patent Application No. 10-2013-0071774, filed on Jun. 21, 2013, in the Korean Intellectual Property Office, the contents of which are herein incorporated by reference in their entirety.

### BACKGROUND OF THE INVENTION

Example embodiments of the inventive concepts relate to a semiconductor package and a method of fabricating the same.

Semiconductor package structures have been developed to increase integration densities of the semiconductor packages and signal transmission speeds of semiconductor devices. For example, there is a system-in-package (SIP) structure, in which all of a memory chip and a logic chip driving the memory chip are provided. However, the SIP structure suffers from various technical difficulties, such as an increase of signal interference and a low signal routability, because all signal bumps are disposed in a given small area.

### SUMMARY

Example embodiments of the inventive concepts provide a semiconductor package capable of improving routability and reliability.

According to an aspect of the present inventive concepts, a semiconductor package may include a package substrate, a first semiconductor chip on the package substrate, and at least one second semiconductor chip on the first semiconductor chip and including bumps. The bumps include memory I/O bumps and power/ground voltage bumps, and the memory I/O bumps may be adjacent to a center of the first semiconductor chip.

In some embodiments, the power/ground voltage bumps may be adjacent to an edge of the first semiconductor chip. In some embodiments, the first semiconductor chip may include through vias electrically connected to the bumps, respectively.

In some embodiments, the at least one second semiconductor chip may include two second semiconductor chips side by side on the first semiconductor chip. In some embodiments, the power/ground voltage bumps may be adjacent to an edge of the first semiconductor chip. In some embodiments, the bumps may further include dummy bumps, to which any signal from the first semiconductor chip may be not applied, and the dummy bumps may be adjacent to an edge of the first semiconductor chip.

In some embodiments, the second semiconductor chip may include internal circuits provided therein and the internal circuits may overlap the dummy bumps.

In some embodiments, one of the second semiconductor chips may have an orientation rotated by 180 degree with respect to the other of the second semiconductor chips. In some embodiments, the first semiconductor chip may be a logic chip and the second semiconductor chips may be memory chips, the first semiconductor chip may further include internal circuits connected to the bumps to exchange signals through the bumps, respectively. The internal circuits in the first semiconductor chip may be arranged adjacent to respective ones of the bumps, according to an arrangement of the second semiconductor chips.

In some embodiments, the semiconductor package may further include outer solder balls that may be attached on a bottom surface of the package substrate and may be applied with power or ground voltage signals with the same voltage level.

In some embodiments, the at least one second semiconductor chip may further include a conductive pad under the at least one second semiconductor chip and connected to the bump, and a passivation layer interposed between the conductive pad and the bump to cover a bottom of the at least one second semiconductor chip. In some embodiments, the conductive pad has an uneven top surface.

In some embodiments, the at least one second semiconductor chip may further include a conductive pad under the at least one second semiconductor chip and connected to the bump, and a passivation layer covering a bottom of the at least one second semiconductor chip and a portion of the conductive pad. The conductive pad has a flat top surface.

In some embodiments, the second semiconductor chip may include a portion protruding from a sidewall of the first semiconductor chip.

In some embodiments, the semiconductor package may further include third semiconductor chips side by side on the second semiconductor chips. The second semiconductor chips further include through vias provided therein and electrically connected to the bumps.

In some embodiments, the first and second semiconductor chips may be mounted in a flip-chip bonding manner.

In accordance with another aspect of the present inventive concepts, a semiconductor package may include a package substrate, a first semiconductor chip on the package substrate comprising first memory I/O bumps and first power/ground voltage bumps and at least one second semiconductor chip on the first semiconductor chip which includes second memory I/O bumps and second power/ground voltage bumps. The first and second memory I/O bumps are adjacent to a center of the first semiconductor chip and the first and second power/ground voltage bumps are adjacent an edge region of at least one of the first semiconductor chip and the second semiconductor chip.

In some embodiments, the first semiconductor chip includes the first memory I/O bumps on a bottom surface of the first semiconductor chip and a top surface of the first semiconductor chip, and first through vias electrically connect the first memory I/O bumps on the bottom and the top surfaces of the first semiconductor chip and the second memory I/O bumps. The first semiconductor chip includes the first power/ground voltage bumps on a bottom surface of the first semiconductor chip and a top surface of the first semiconductor chip, and first through vias electrically connect the first power/ground voltage bumps on the bottom and the top surfaces of the first semiconductor chip and the second power/ground voltage bumps.

In some embodiments, the at least one second semiconductor chip includes two second semiconductor chips side by side on the first semiconductor chip.

In some embodiments, the at least one second semiconductor chip further includes conductive pads under the at least one second semiconductor chip and connected to the second memory I/O bumps and a passivation layer interposed between the conductive pads and the second memory I/O bump to cover a bottom of the second semiconductor chip. The second memory I/O bumps have an uneven top surface.

In some embodiments, the at least one second semiconductor chip further includes conductive pads under the at least one second semiconductor chip and connected to the second memory I/O bumps and a passivation layer covering a bottom of the at least one second semiconductor chip and a portion of the conductive pads. The conductive pads have a flat top surface.

### BRIEF DESCRIPTION OF THE DRAWINGS

The foregoing and other features and advantages of the inventive concepts will be apparent from the more particular description of embodiments of the inventive concepts, as illustrated in the accompanying drawings in which like reference characters refer to the same parts throughout the different views. The drawings are not necessarily to scale, emphasis instead being placed upon illustrating the principles of the inventive concepts.

FIG. 1 is a plan view illustrating a semiconductor package according to an example embodiment of the present inventive concepts.

FIG. 2 is a sectional view taken along a line A-A′ of the semiconductor package of FIG. 1 in accordance with an example embodiment of the present inventive concepts.

FIGS. 3A and 3B are enlarged sectional views of a portion P1 of the semiconductor package of FIG. 2 in accordance with an example embodiment of the present inventive concepts.

FIGS. 4A through 4C are sectional views illustrating a method of fabricating a semiconductor package in accordance with an example embodiment of the present inventive concepts.

FIG. 5 is a plan view illustrating a semiconductor package according to an example embodiment of the present inventive concepts.

FIG. 6 is a sectional view taken along a line A-A′ of the semiconductor package of FIG. 5 in accordance with an example embodiment of the present inventive concepts.

FIG. 7 is a plan view illustrating a semiconductor package according to an example embodiment of the present inventive concepts.

FIG. 8 is a sectional view taken along a line A-A′ of the semiconductor package of FIG. 7 in accordance with an example embodiment of the present inventive concepts.

FIG. 9 is an enlarged sectional view of a portion P1 of the semiconductor package of FIG. 8 in accordance with an example embodiment of the present inventive concepts.

FIG. 10 is a sectional view illustrating a semiconductor package according to an example embodiment of the present inventive concepts.

FIG. 11 is a sectional view illustrating a semiconductor package according to an example embodiment of the present inventive concepts.

FIG. 12 is a perspective view illustrating an electronic system including at least one of the semiconductor packages according to the example embodiments of the present inventive concepts.

FIG. 13 is a schematic block diagram illustrating an electronic system including at least one of the semiconductor packages according to the example embodiments of the present inventive concepts.

FIG. 14 is a block diagram illustrating an example of electronic systems including semiconductor packages according to the example embodiments of the present inventive concepts.

### DETAILED DESCRIPTION

Various example embodiments of the present inventive concepts will now be described more fully hereinafter with reference to the accompanying drawings, in which some example embodiments are shown. The present inventive concepts may, however, be embodied in many different forms and should not be construed as being limited to the example embodiments set forth herein.

It will be understood that when an element or layer is referred to as being “on,” “connected to” or “coupled to” another element or layer, it can be directly on, connected or coupled to the other element or layer or intervening elements or layers may be present. In contrast, when an element or layer is referred to as being “directly on,” “directly connected to” or “directly coupled to” another element or layer, there are no intervening elements or layers present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises”, “comprising”, “includes” and/or “including,” when used in this specification, specify the presence of stated features, integers, steps, operations, elements and/or components, but do not preclude the presence or addition of one or more other features, integers, steps, operations, elements, components and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

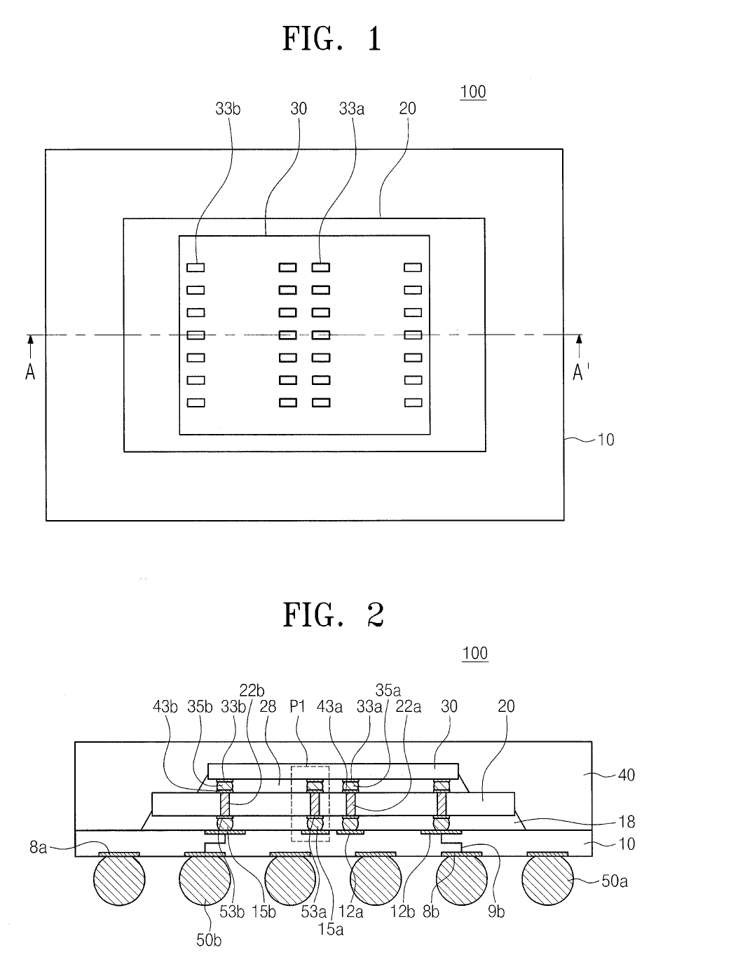

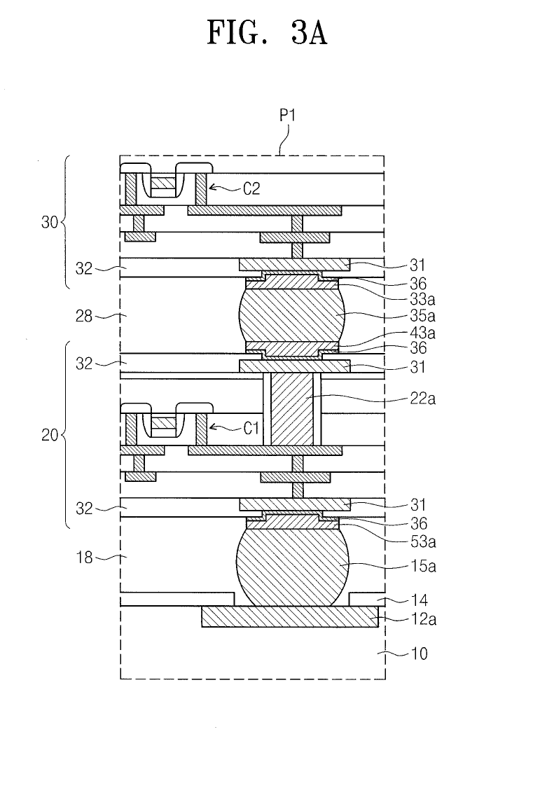

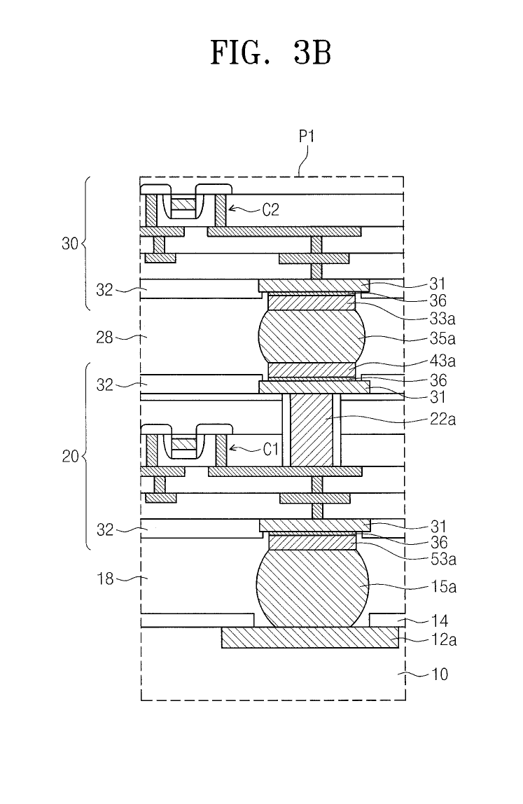

FIG. 1 is a plan view illustrating a semiconductor package according to an example embodiment of the present inventive concepts. FIG. 2 is a sectional view taken along a line A-A′ of the semiconductor package of FIG. 1 in accordance with an example embodiment of the present inventive concepts. FIGS. 3A and 3B are enlarged sectional views of a portion P1 of the semiconductor package of FIG. 2 in accordance with an example embodiment of the present inventive concepts.

Referring to FIGS. 1 through 3B, a semiconductor package 100 may include a package substrate 10 and first and second semiconductor chips 20 and 30, respectively, sequentially stacked on the package substrate 10. Upper ball lands 12a and 12b may be provided on a top surface of the package substrate 10, and lower ball lands 8a and 8b may be provided on a bottom surface of the package substrate 10. The upper ball lands 12a and 12b may include first upper ball lands 12a and second upper ball lands 12b. The first upper ball lands 12a and the second upper ball lands 12b may each include a plurality of upper ball lands. The lower ball lands 8a and 8b may include first lower ball lands 8a and second lower ball lands 8b. The first lower ball lands 8a and the second lower ball lands 8b may each include a plurality of lower ball lands.

Internal lines 9b may be provided in the package substrate 10 to connect the second upper ball lands 12b to the second lower ball lands 8b. First and second outer solder balls 50a and 50b may be attached on the first and second lower ball lands 8a and 8b, respectively. The first outer solder balls 50a and the second outer solder balls 50b may each include a plurality of outer solder balls.

The first semiconductor chip 20 may be a logic or driving chip for driving the second semiconductor chip 30. The first semiconductor chip 20 may be, for example, a digital or analog baseband modem chip. The first semiconductor chip 20 may include at least one first internal circuit C1, as illustrated in FIGS. 3A and 3B, composed of a plurality of intellectual property (IP) blocks. In some example embodiments, a central processor unit (CPU), a graphic processor unit (GPU), and a universal serial bus (USB) may be provided in the IP blocks. The second semiconductor chip 30 may be a memory chip, such as a DRAM chip. The second semiconductor chip 30 may include at least one second internal circuit C2, as illustrated in FIGS. 3A and 3B, that is disposed in several regions, for example, disposed in a cell array region and a peripheral circuit region. Each of the internal circuits C1 and C2 may include transistors, wires, capacitors, and/or resistors.

The first semiconductor chip 20 may include first upper bumps 43a and second upper bumps 43b provided thereon, first lower bumps 53a and second lower bumps 53b provided thereunder, and first and second through vias 22a and 22b connecting them electrically to each other. The first through vias 22a electrically connect the first upper bumps 43a to the first lower bumps 53a. The second through vias 22b electrically connect the second upper bumps 43b to the first lower bumps 53b. The first upper bumps 43a and the second upper bumps 43b may each include a plurality of upper bumps. The first lower bumps 53a and the second lower bumps 53b may each include a plurality of lower bumps. The first through vias 22a and second through vias 22b may each include a plurality of through vias.

The second semiconductor chip 30 may include third lower bumps 33a and fourth lower bumps 33b provided thereunder. The second lower bumps 33a and the fourth lower bumps 33b may each include a plurality of lower bumps. The first semiconductor chip 20 may be mounted in a flip-chip bonding manner on the package substrate 10 using first internal solder balls 15a and second internal solder balls 15b. The first internal solder balls 15a and the second internal solder balls 15b may each include a plurality of internal solder balls. The second semiconductor chip 30 may be mounted in a flip-chip bonding manner on the first semiconductor chip 20 using third internal solder balls 35a and fourth internal solder balls 35b. The third internal solder balls 55a and the fourth internal solder balls 55b may each include a plurality of internal solder balls. A first underfill resin layer 18 may be interposed between the first semiconductor chip 20 and the package substrate 10, and a second underfill resin layer 28 may be interposed between the second semiconductor chip 30 and the first semiconductor chip 20. The first and second semiconductor chips 20 and 30 may be covered with a mold layer 40.

The third lower bumps 33a may serve as data I/O terminals for inputting or outputting data to or from the second semiconductor chip 30. The third lower bumps 33a may be provided adjacent to a central region of the second semiconductor chip 30 and/or a central region of the first semiconductor chip 20. The first upper bumps 43a may be coupled to the third lower bumps 33a, respectively by the third internal solder balls 35a. Data signals to be produced in the first internal circuits C1 of the first semiconductor chip 20 may be transmitted to the second internal circuit C2 of the second semiconductor chip 30 via the first through vias 22a, the first upper bumps 43a, the third internal solder balls 35a, and the third lower bumps 33a. Similarly, data signals to be produced in the second internal circuit C2 of the second semiconductor chip 30 may be transmitted to the first internal circuit C1 of the first semiconductor chip 20 via the third lower bumps 33a, the third internal solder balls 35a, the first upper bumps 43a, and the first through vias 22a. The first lower bumps 53a may be in contact with the first upper ball lands 12a through the first internal solder ball 15a.

The fourth lower bumps 33b may serve as power/ground voltage terminals for applying power/ground voltages to the second semiconductor chip 30. The fourth lower bumps 33b may be disposed adjacent to an edge region of the second semiconductor chip 30 and/or an edge region of the first semiconductor chip 20. The second upper bumps 43b may be coupled to the fourth lower bumps 33b, respectively by the fourth internal solder balls 35b. The fourth lower bumps 33b, the fourth internal solder balls 35b, the second upper bumps 43b, the second through vias 22b, the second lower bumps 53b, the second internal solder balls 15b, the second upper ball lands 12b, the internal lines 9b, the second lower ball lands 8b, and the second outer solder balls 50b may be electrically connected to serve as electric paths for transmitting the power/ground voltages from an external device to the second semiconductor chip 30. In some example embodiments, a power or ground voltage signal applied to the second outer solder balls 50b may have substantially the same voltage level.

In some example embodiments, the third and fourth lower bumps 33a and 33b serving as the memory I/O terminals and the power/ground voltage terminals, respectively, may be disposed on different regions of the second semiconductor chip 30. This makes it possible to reduce interference between signals and enhance signal routability of interconnection.

Referring to FIG. 3A, conductive pads 31 may be provided below the second semiconductor chip 30 and be electrically connected to the third and fourth lower bumps 33a and 33b, respectively. That is, the conductive pads 31 are disposed between the second semiconductor chip 30 and the third and fourth lower bumps 33a and 33b, respectively. A seed layer 36 serving as a diffusion-barrier layer may be interposed between the conductive pads 31 and the third and fourth lower bumps 33a and 33b. A bottom surface of the second semiconductor chip 30 may be covered with a passivation layer 32. The passivation layer 32 may cover a portion of the conductive pads 31 and include a portion interposed between the conductive pads 31 and the third and fourth lower bumps 33a and 33b. The seed layer 36 may be interposed between the passivation layer 32 and the third and fourth lower bumps 33a and 33b. Accordingly, the third and fourth lower bumps 33a and 33b may have an uneven top surface. Due to the portion of the passivation layer 32 interposed between the conductive pads 31 and the third and fourth lower bumps 33a and 33b, physical stress exerted on edge portions of the third and fourth lower bumps 33a and 33b may be relieved. Other bumps, for example, first and second upper bumps 43a and 43b, first and second lower bumps 53a and 53b and elements adjacent thereto may be configured to have this structural structure. Accordingly, it is possible to prevent a joint cracking problem or a damage of the internal circuits C1 and C2.

Specifically, referring to FIG. 3A, conductive pads 31 may be provided on the first semiconductor chip 20 and be electrically connected to the first and second upper bumps 43a and 43b, respectively. That is, the conductive pads 31 are disposed between the first semiconductor chip 20 and the first and second upper bumps 43a and 43b, respectively. A seed layer 36 serving as a diffusion-barrier layer may be interposed between the conductive pads 31 and the first and second upper bumps 43a and 43b. An upper surface of the first semiconductor chip 20 may be covered with a passivation layer 32. The passivation layer 32 may cover a portion of the conductive pads 31 and include a portion interposed between the conductive pads 31 and the first and second upper bumps 43a and 43b. The seed layer 36 may be interposed between the passivation layer 32 and the first and second upper bumps 43a and 43b. Accordingly, the first and second upper bumps 43a and 43b may have an uneven bottom surface.

Referring to FIG. 3A, conductive pads 31 may be provided below the first semiconductor chip 20 and be electrically connected to the first and second lower bumps 53a and 53b, respectively. That is, the conductive pads 31 are disposed between the first semiconductor chip 20 and the first and second lower bumps 53a and 53b, respectively. A seed layer 36 serving as a diffusion-barrier layer may be interposed between the conductive pads 31 and the first and second lower bumps 53a and 53b. A bottom surface of the first semiconductor chip 20 may be covered with a passivation layer 32. The passivation layer 32 may cover a portion of the conductive pads 31 and include a portion interposed between the conductive pads 31 and the first and second lower bumps 53a and 53b. The seed layer 36 may be interposed between the passivation layer 32 and first and second lower bumps 53a and 53b.

Referring to FIG. 3B, in an alternative embodiment the passivation layer 32 may not be interposed between the conductive pads 31 and the third and fourth lower bumps 33a, 33b, the first and second upper bumps 43a, 43b, and the first and second lower bumps 53a and 53b. Accordingly, the third and fourth lower bumps 33a, 33b, the first and second upper bumps 43a, 43b, and the first and second lower bumps may have flat top and bottom surfaces.

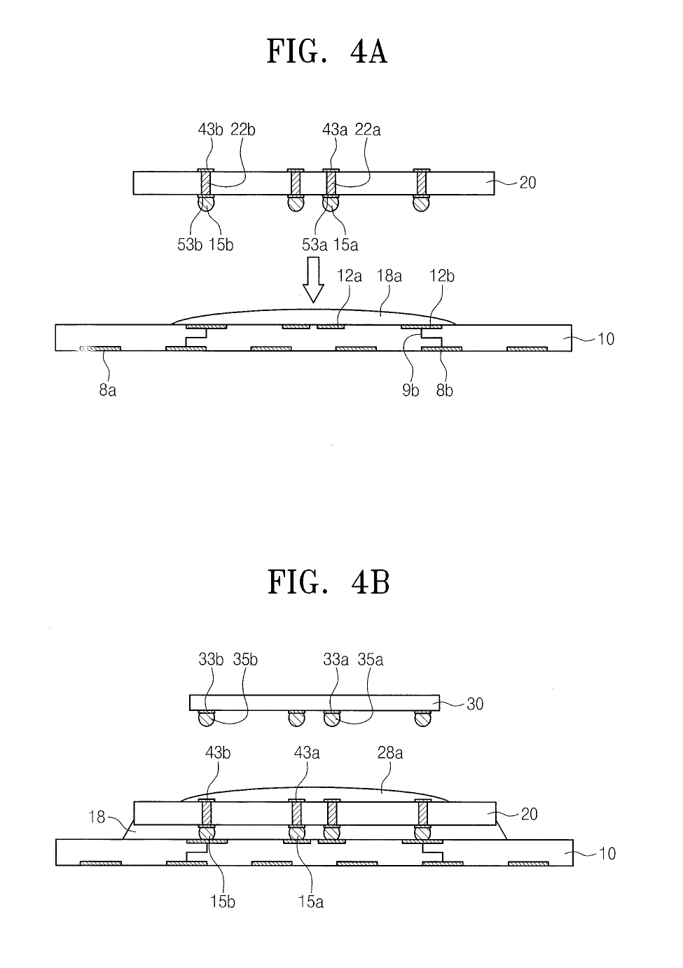

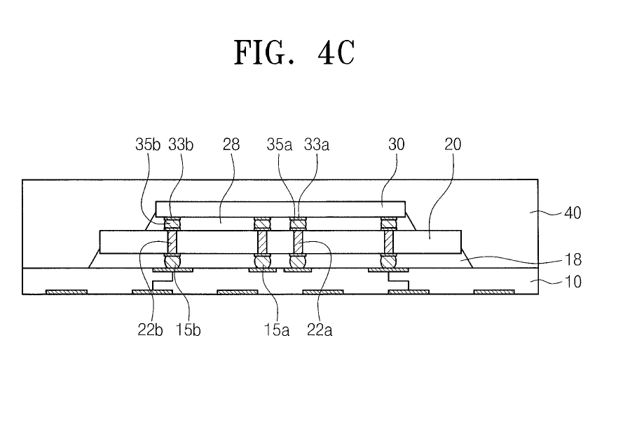

FIGS. 4A through 4C are sectional views illustrating a method of fabricating a semiconductor package, for example, with a section of the semiconductor package of FIG. 2 in accordance with an example embodiment of the present inventive concepts.

Referring to FIG. 4A, a first non-conductive layer 18a, for example, a non-conductive film or a non-conductive paste, may be disposed on the package substrate 10. The first internal solder balls 15a and 15b may be attached on the bottom surface of the first semiconductor chip 20, and, then, the first semiconductor chip 20 having the first internal solder balls 15a and 15b thereon may be disposed on the package substrate 10. Thereafter, a first heating process may be performed to attach the first internal solder balls 15a and 15b to the package substrate 10. During the first heating process, the first non-conductive layer 18a may be melted to form the first underfill resin layer 18 filling a gap between the package substrate 10 and the first semiconductor chip 20. During this process, since a physical stress is not concentrated on edge portions of the first and second lower bumps 53a and 53b and is distributed on the whole region of the first semiconductor chip 20, problems such as cracking or cell damage may be prevented.

Referring to FIG. 4B, when mounting of the first semiconductor chip 20 is finished, a second non-conductive layer 28a, for example, a non-conductive film or a non-conductive paste, may be disposed on the top surface of the first semiconductor chip 20. The second internal solder balls 35a and 35b may be attached on the bottom surface of the second semiconductor chip 30, and then, the second semiconductor chip 20 having the second internal solder balls thereon may be disposed on the first semiconductor chip 20. Thereafter, a second heating process may be performed to attach the second internal solder balls 35a and 35b to the first semiconductor chip 20. During the second heating process, the second non-conductive layer 28a may be melted to form the second underfill resin layer 28 filling a gap between the first and second semiconductor chips 20 and 30. During this process, since a physical stress is not concentrated on edge portions of the third and fourth lower bumps 33a, 33b and the first and second upper bumps 43a and 43b and is distributed on the whole region of the second semiconductor chip 30, the problems such as cracking or cell damage may be prevented.

Referring to FIG. 4C, a mold process may be performed to form the mold layer 40 covering the first and second semiconductor chips 20 and 30.

Thereafter, as shown in FIG. 2, the first and second outer solder balls 50a and 50b may be attached on the bottom surface of the package substrate 10.

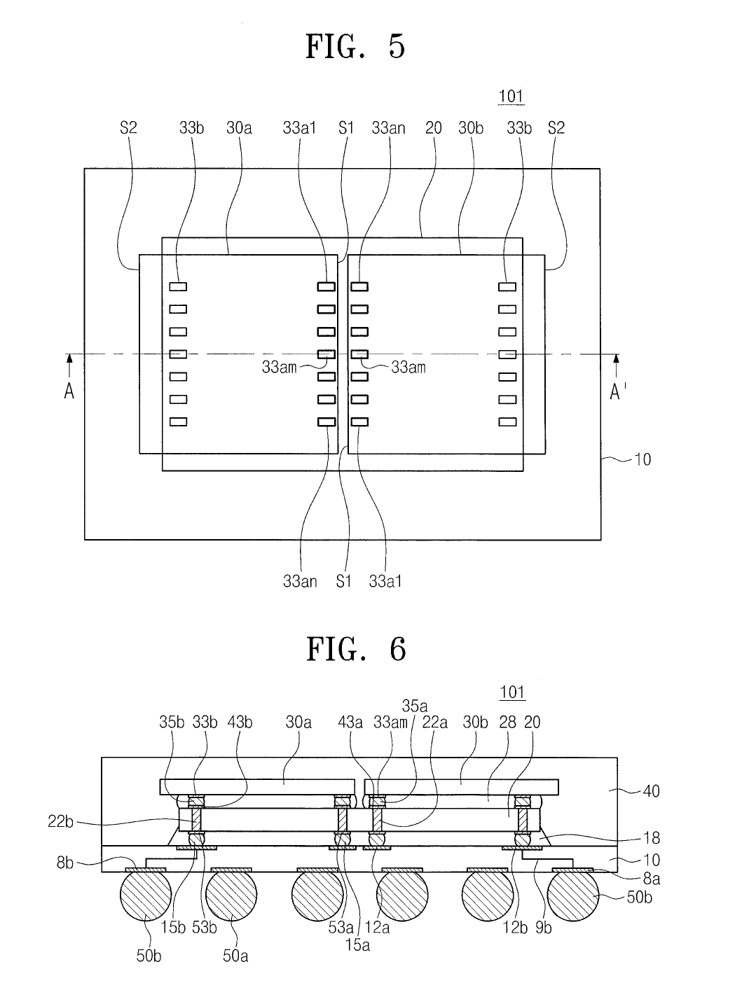

FIG. 5 is a plan view illustrating a semiconductor package according to an example embodiment of the present inventive concepts. FIG. 6 is a sectional view taken along a line A-A′ of the semiconductor package of FIG. 5 in accordance with an example embodiment of the present inventive concepts.

Referring to FIGS. 5 and 6, according to the present embodiment, a semiconductor package 101 may include the package substrate 10 and the first semiconductor chip 20 mounted thereon. Second semiconductor chips 30a and 30b may be mounted side by side on the first semiconductor chip 20. The second semiconductor chips 30a and 30b may be the same kind of memory chip, for example, DRAM chips. Each of the second semiconductor chips 30a and 30b may include third lower bumps 33a1-33an (where 1<m<n and m and n are natural numbers greater than one) and the fourth lower bumps 33b. The third lower bumps 33a1-33an may be disposed adjacent to adjacently-facing sidewalls S1 of the second semiconductor chips 30a and 30b or adjacent to a center of the first semiconductor chip 20. The fourth lower bumps 33b may be disposed adjacent to distantly-facing sidewalls S2 of the second semiconductor chips 30a and 30b or adjacent to an edge of the first semiconductor chip 20. One, for example, 30a, of the second semiconductor chips 30a and 30b may be disposed to have an orientation rotated by 180 degree with respect to the other, for example, 30b, of the second semiconductor chips 30a and 30b. Accordingly, in terms of arrangement of the third lower bumps 33a1-33an, the second semiconductor chips 30a and 30b may be opposite to each other. For example, in the second semiconductor chip 30a, the first lower bump 33a1 of the third lower bumps is disposed at a back position and the last lower bump 33an of the third lower bumps is disposed at a front position. While in the second semiconductor chip 30b, the first lower bump 33a1 of the third lower bumps is disposed at the front position and the last lower bump 33an of the third lower bumps is disposed at the back position. This means that to exchange data signals with the third lower bumps 33a1-33an, the first semiconductor chip 20 may have modifications in terms of arrangements, positions, and/or designs of the internal circuits and data I/O terminals. For example, the data I/O terminals of the first semiconductor chip 20 may be changed in such a way that positions thereof are adjacent to respective ones of the third lower bumps 33a1-33an. This makes it possible to reduce a path length for signal transmission and thereby to improve a signal transmission speed. Except for this difference, the semiconductor package 101 may be configured to have substantially the same features as the semiconductor package 100 of the example embodiment of FIGS. 1-4C.

According to the present embodiment of FIG. 5, since the second semiconductor chips 30a and 30b are disposed side by side, rather than vertically stacked on each other, there is no need to form a TSV penetrating the second semiconductor chips. Accordingly, compared with a structure including vertically-stacked second semiconductor chips 30a and 30b, it is possible to reduce fabrication cost.

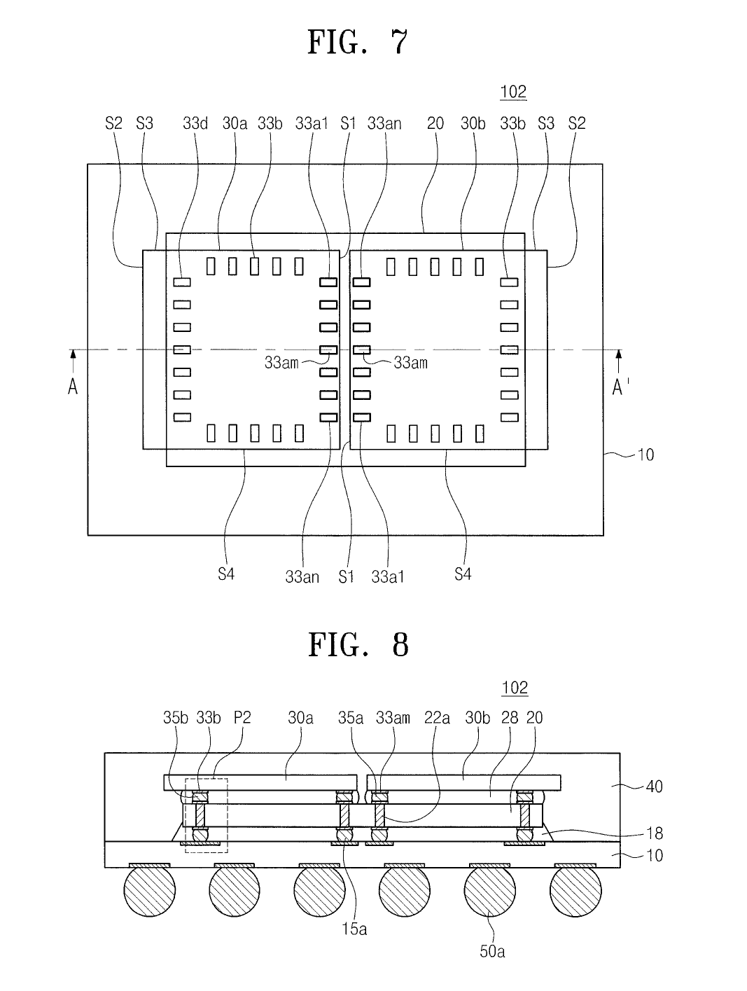

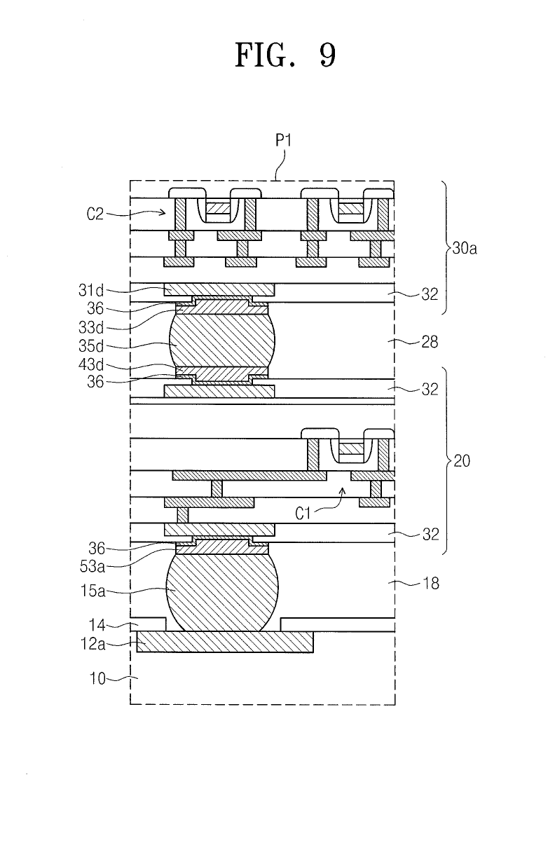

FIG. 7 is a plan view illustrating a semiconductor package according to an example embodiment of the present inventive concepts. FIG. 8 is a sectional view taken along a line A-A′ of the semiconductor package of FIG. 7 in accordance with an example embodiment of the present inventive concepts. FIG. 9 is an enlarged sectional view of a portion P1 of the semiconductor package of FIG. 8 in accordance with an example embodiment of the present inventive concepts.

Referring to FIGS. 7 through 9, according to the present embodiment, a semiconductor package 102 may include the second semiconductor chips 30a and 30b, each of which includes fifth lower bumps 33d, in addition to the third bumps 33a1-33an and the fourth lower bumps 33b. The fifth lower bumps 33d may be configured not to exchange any electrical signal with the first semiconductor chip 20, thereby serving as dummy bumps. The fifth lower bumps 33d may be disposed to be adjacent to the second sidewalls S2 of the second semiconductor chips 30a and 30b. The fourth lower bumps 33b may be disposed adjacent to third and fourth sidewalls S3 and S4. The third and fourth sidewalls S3 and S4 connect the first sidewalls S1 to the second sidewalls S2 in each of the second semiconductor chips 30a and 30b. The first semiconductor chip 20 may further include third upper bumps 43d to be coupled to the fifth lower bumps 33d. Fifth internal solder balls 35d may be interposed between the fifth lower bumps 33d and the third upper bumps 43d. These may support the second semiconductor chips 30a and 30b, and, thus, it is possible to maintain horizontality of the second semiconductor chips 30a and 30b. In the cell array region and the peripheral circuit region of the second semiconductor chips 30a and 30b, the second internal circuits C2, as illustrated in FIG. 9, may be disposed to overlap the fourth lower bumps 33b. For example, in a plan view, transistors or multi-layered interconnections may be disposed to overlap the fourth lower bumps 33b. The passivation layer 32 may be interposed between the conductive pads 31d and the third, fourth, and fifth lower bumps 33a, 33b, and 33d, thereby reducing a physical stress exerted on edge portions of the twenty-first, twenty-second, and twenty-third lower bumps 33a, 33b, and 33d. Except for this difference, the semiconductor package 102 may be configured to have substantially the same features as the semiconductor package 101 of the example embodiment of FIGS. 5 and 6.

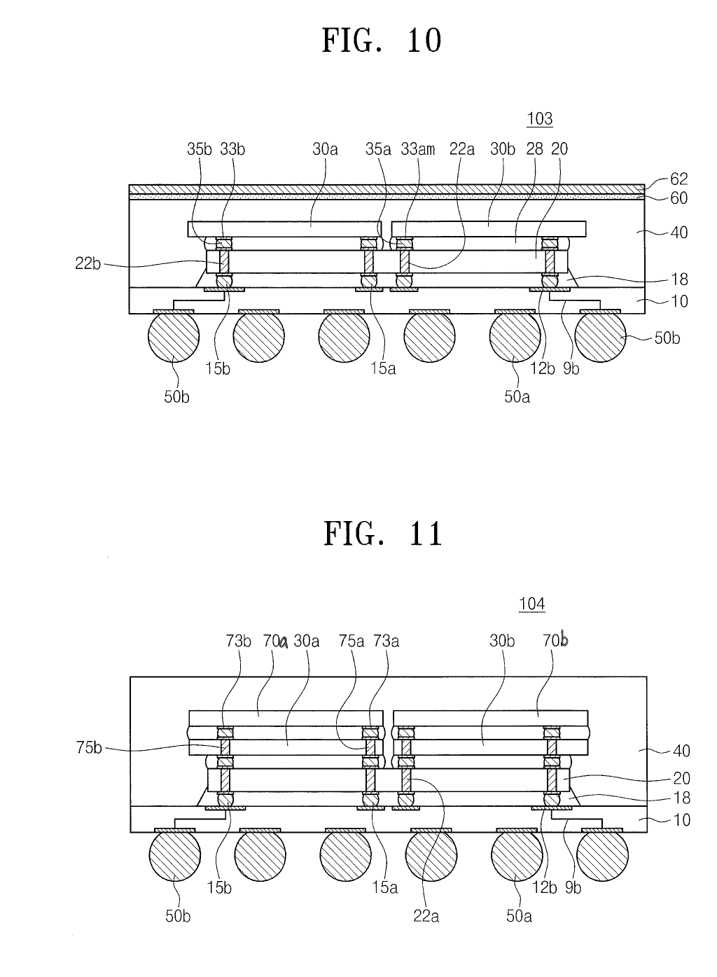

FIG. 10 is a sectional view illustrating a semiconductor package according to an example embodiment of the present inventive concepts.

Referring to FIG. 10, according to the present embodiment, a semiconductor package 103 may further include a thermal boundary layer 60 and a heat-dissipating layer 62 that are sequentially stacked on the semiconductor package 101 of FIGS. 5 and 6. Alternatively, the thermal boundary layer 60 and the heat-dissipating layer 62 may be sequentially stacked on the semiconductor packages 100 or 102. The thermal boundary layer 60 may include an adhesive layer, a thermal grease layer, or a thermal epoxy layer, at least one of which contains metallic solid particles. The heat-dissipating layer 62 may be a metal plate or a flexible metal tape. Due to the presence of the heat-dissipating layer 62, it is possible to exhaust heat generated from the semiconductor package 103 to the outside. This makes it possible to improve reliability of the semiconductor package 103 and reduce malfunctions of the semiconductor package 103. Except for this difference, the semiconductor package 103 may be configured to have substantially the same features as the semiconductor package 101 of the example embodiment of FIGS. 5 and 6.

FIG. 11 is a sectional view illustrating a semiconductor package according to an example embodiment of the present inventive concepts.

Referring to FIG. 11, according to the present embodiment, a semiconductor package 104 may have a structure modified from the semiconductor package 101 of FIGS. 5 and 6. For example, the semiconductor package 104 may include third semiconductor chips 70a and 70b provided on the second semiconductor chips 30a and 30b. The third semiconductor chips 70a and 70b may be the same kind as the second semiconductor chips 30a and 30b. For example, the second and third semiconductor chips 30a, 30b, 70a and 70b may be the same kind of memory chip. Fifth and sixth lower bumps 73a and 73b may be provided on bottom surfaces of the third semiconductor chips 70a and 70b. Through vias 75a and 75b may be provided in the second semiconductor chips 30a and 30b and be electrically connected to the fifth and sixth lower bumps 73a and 73b, respectively. Except for this difference, the semiconductor package 103 may be configured to have substantially the same features as the semiconductor package 101 of the example embodiment of FIGS. 5 and 6. Alternatively the third semiconductor chips may be applied to the other example embodiments of the present inventive concepts.

The afore-described semiconductor package technology may be applied to various kinds of semiconductor devices and package modules with the same.

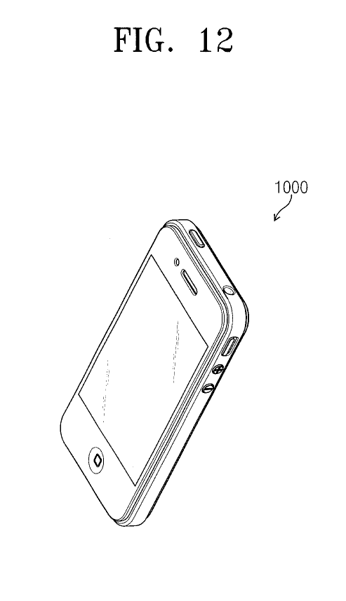

FIG. 12 is a perspective view illustrating an electronic system including at least one of the semiconductor packages according to the example embodiments of the present inventive concepts.

Referring to FIG. 12, semiconductor packages according to the embodiments of the present inventive concepts may be applicable to an electronic system 1000, for example, a smart phone. The semiconductor packages 100-104 described above may be applicable to the electronic system 1000. The semiconductor packages according to the example embodiments of the present inventive concepts may have advantages such as being capable of scaling down and/or realizing high performance. The electronic system including the semiconductor packages according to the embodiments is not limited to the smart phone. For example, the semiconductor packages according to the embodiments may be applicable to a mobile electronic product, a laptop computer, a portable computer, a portable multimedia player (PMP), an MP3 player, a camcorder, a web tablet, a wireless phone, a navigator or a personal digital assistant (PDA).

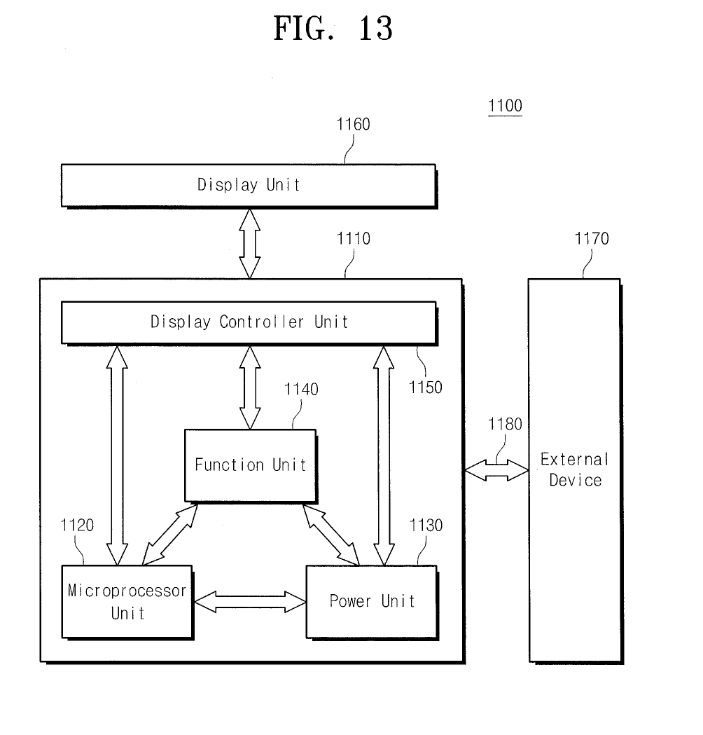

FIG. 13 is a schematic block diagram illustrating an electronic system including at least one of the semiconductor packages according to the example embodiments of the present inventive concepts.

Referring to FIG. 13, the semiconductor package 100-104 described above may be applicable to an electronic system 1100. The electronic system 1100 may include a body 1110, a microprocessor unit 1120, a power unit 1130, a function unit 1140 and a display control unit 1150. The body 1110 may include a set board fowled of a printed circuit board (PCB), and the microprocessor unit 1120, the power unit 1130, the function unit 1140 and the display control unit 1150 may be mounted on and/or in the body 1110.

The power unit 1130 may receive an electric power having a certain voltage from an external battery (not shown) and may generate a plurality of output power signals having different voltages, and the output power signals may be supplied to the microprocessor unit 1120, the function unit 1140 and the display control unit 1150.

The microprocessor unit 1120 may receive one of the output power signals from the power unit 1130 to control the function unit 1140 and a display unit 1160. The function unit 1140 may operate so that the electronic system 1100 executes one of diverse functions. For example, in the event that the electronic system 1100 is a mobile phone, the function unit 1140 may include various components which are capable of executing functions of the mobile phone, for example, a function of dialing, a function of outputting image signals to the display unit 1160 during communication with an external device 1170, and a function of outputting audio signals to speakers during communication with the external device 1170. Further, when the electronic system 1100 includes a camera, the function unit 1140 may correspond to a camera image processor CIP. Moreover, if the electronic system 1100 is connected to a memory card to increase a memory capacity, the function unit 1140 may correspond to a memory card controller. The function unit 1140 may communicate with the external device 1170 through a communication unit 1180 by wireless or cable. Furthermore, in the event that the electronic system 1100 needs a universal serial bus (USB) for function expansion, the function unit 1140 may be an interface controller. The semiconductor packages 100-104 described above may be used in at least one of the microprocessor unit 1120 and the function unit 1140.

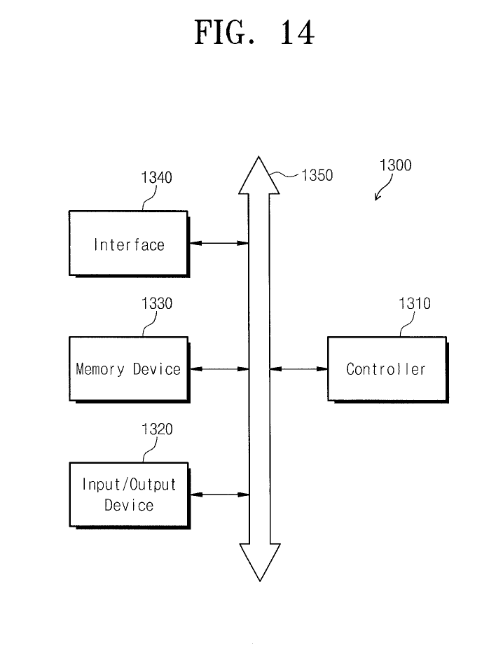

FIG. 14 is a block diagram illustrating an example of electronic systems including the semiconductor packages according to the example embodiments of the present inventive concepts.

Referring to FIG. 14, an electronic system 1300 according to an embodiment may include a controller 1310, an input/output (I/O) device 1320, a memory device 1330 and a data bus 1350. The semiconductor packages 100-104 described above may be applicable to the electronic system 1300. At least two of the controller 1310, the I/O device 1320 and the memory device 1330 may communicate with each other through the data bus 1350. The data bus 1350 may correspond to a path through which electrical signals are transmitted. The controller 1310 may include at least one of a microprocessor, a digital signal processor, a microcontroller and a logic device. The logic device may have a similar function to any one of the microprocessor, the digital signal processor and the microcontroller. The controller 1310 and/or the memory device 1330 may include at least one of the semiconductor packages described in the above embodiments. The I/O device 1320 may include at least one of a keypad, a keyboard and a display device. The memory device 1330 may store data and/or commands executed by the controller 1310. The memory device 1330 may include a volatile memory device and/or a nonvolatile memory device. For example, the memory device 1330 may include a flash memory device to which the package techniques according to the embodiments are applied. The flash memory device may constitute a solid state disk (SSD). In this case, the solid state disk including the flash memory device may stably store a large capacity of data. The electronic system 1300 may further include an interface unit 1340. The interface unit 1340 may transmit data to a communication network or may receive data from a communication network. The interface unit 1340 may operate by wireless or cable. For example, the interface unit 1340 may include an antenna for wireless communication or a transceiver for cable communication. Although not shown in the drawings, the electronic system 1300 may further include an application chipset and/or a camera image processor.

According to example embodiments of the present inventive concepts, the memory I/O bumps and the power/ground voltage bumps are disposed at different positions from each other, and thus, it is possible to improve routability of interconnections.

According to other example embodiments of the present inventive concepts, since the second semiconductor chips are disposed side by side, there is no need to form through vias. Accordingly, it is possible to reduce fabrication cost of the semiconductor package.

According to still other example embodiments of the present inventive concepts, the passivation layer is interposed between the conductive pads and the bumps, thereby preventing a physical stress from being concentrated on an edge of the bumps. Accordingly, the semiconductor package can have improved reliability.

While example embodiments of the inventive concepts have been particularly shown and described, it will be understood by one of ordinary skill in the art that variations in form and detail may be made therein without departing from the spirit and scope of the attached claims.

What is claimed is:

1. A semiconductor package, comprising:
a package substrate;
a first semiconductor chip on the package substrate; and
at least one second semiconductor chip on the first semiconductor chip and including bumps,
wherein the bumps comprise memory I/O bumps and power/ground voltage bumps, and wherein the memory I/O bumps are adjacent to a center of the first semiconductor chip.

2. The semiconductor package of claim 1, wherein the power/ground voltage bumps are adjacent to an edge of the first semiconductor chip.

3. The semiconductor package of claim 2, wherein the first semiconductor chip comprises through vias electrically connected to the bumps, respectively.

4. The semiconductor package of claim 1, wherein the at least one second semiconductor chip comprises two second semiconductor chips side by side on the first semiconductor chip.

5. The semiconductor package of claim 4, wherein the power/ground voltage bumps are adjacent to an edge of the first semiconductor chip.

6. The semiconductor package of claim 4, wherein the bumps further comprises dummy bumps, to which any signal from the first semiconductor chip are not applied, and
the dummy bumps are adjacent to an edge of the first semiconductor chip.

7. The semiconductor package of claim 6, wherein the second semiconductor chip comprises internal circuits provided therein and, wherein the internal circuits overlap the dummy bumps.

8. The semiconductor package of claim 4, wherein one of the second semiconductor chips have an orientation rotated by 180 degree with respect to the other of the second semiconductor chips.

9. The semiconductor package of claim 8, wherein the first semiconductor chip is a logic chip and the second semiconductor chips are memory chips,
the first semiconductor chip further comprises internal circuits connected to the bumps to exchange signals through the bumps, respectively, and
wherein the internal circuits in the first semiconductor chip are arranged adjacent to respective ones of the bumps, according to an arrangement of the second semiconductor chips.

10. The semiconductor package of claim 1, further comprising outer solder balls that are attached on a bottom surface of the package substrate and are applied with power or ground voltage signals of the same voltage level.

11. The semiconductor package of claim 1, wherein the at least one second semiconductor chip further comprises:
a conductive pad under the at least one second semiconductor chip and connected to the bump; and
a passivation layer interposed between the conductive pad and the bump to cover a bottom of the at least one second semiconductor chip.

12. The semiconductor package of claim 11, wherein the bump has an uneven top surface.

13. The semiconductor package of claim 1, wherein the at least one second semiconductor chip further comprises:
a conductive pad under the second semiconductor chip and connected to the bump; and
a passivation layer covering a bottom of the at least one second semiconductor chip and a portion of the conductive pad,
wherein the conductive pad has a flat top surface.

14. The semiconductor package of claim 4, wherein the second semiconductor chip comprises a portion laterally protruding from a sidewall of the first semiconductor chip.

15. The semiconductor package of claim 4, further comprising third semiconductor chips side by side on the second semiconductor chips,
wherein the second semiconductor chips further comprise through vias provided therein and electrically connected to the bumps.

16. A semiconductor package, comprising:
a package substrate;
a first semiconductor chip on the package substrate comprising first memory I/O bumps and first power/ground voltage bumps; and
at least one second semiconductor chip on the first semiconductor chip and comprising second memory I/O bumps and second power/ground voltage bumps,
wherein the first and second memory I/O bumps are adjacent to a center of the first semiconductor chip, and
wherein the first and second power/ground voltage bumps are adjacent an edge region of at least one of the first semiconductor chip and the second semiconductor chip.

17. The semiconductor package of claim 16, wherein the first semiconductor chip comprises the first memory I/O bumps on a bottom surface of the first semiconductor chip and a top surface of the first semiconductor chip, and wherein first through vias electrically connect the first memory I/O bumps on the bottom and the top surfaces of the first semiconductor chip and the second memory I/O bumps, and
wherein the first semiconductor chip comprises the first power/ground voltage bumps on a bottom surface of the first semiconductor chip and a top surface of the first semiconductor chip, and wherein first through vias electrically connect the first power/ground voltage bumps on the bottom and the top surfaces of the first semiconductor chip and the second power/ground voltage bumps.

18. The semiconductor package of claim 16, wherein the at least one second semiconductor chip comprises two second semiconductor chips side by side on the first semiconductor chip.

19. The semiconductor package of claim 16, wherein the at least one second semiconductor chip further comprises:
conductive pads under the at least one second semiconductor chip and connected to the second memory I/O bumps; and
a passivation layer interposed between the conductive pads and the second memory I/O bump to cover a bottom of the second semiconductor chip,
wherein the second memory I/O bumps have an uneven top surface.

20. The semiconductor package of claim 16, wherein the at least one second semiconductor chip further comprises:
conductive pads under the at least one second semiconductor chip and connected to the second memory I/O bumps; and
a passivation layer covering a bottom of the at least one second semiconductor chip and a portion of the conductive pads,
wherein the conductive pads have a flat top surface.
